(19) United States
(12) Patent Application Publication
(10) Pub. No.: US 2026/0179696 A1
(43) Pub. Date: Jun. 25, 2026

(54) SEMICONDUCTOR DEVICES AND OPERATION METHODS THEREOF

(71) Applicant: Yangtze Memory Technologies Co., Ltd., Wuhan (CN)

(72) Inventors: Man HU, Wuhan (CN); Xiangnan ZHAO, Wuhan (CN); Songmin JIANG, Wuhan (CN); Hongtao LIU, Wuhan (CN); Kaikai YOU, Wuhan (CN)

(21) Appl. No.: 19/024,884

(22) Filed: Jan. 16, 2025

Related U.S. Application Data
(63) Continuation of application No. PCT/CN2024/140606, filed on Dec. 19, 2024.

(51) Int. Cl. G11C 16/34; G11C 16/04; G11C 16/10

(52) U.S. Cl. CPC G11C 16/3427; G11C 16/0483; G11C 16/10

(57) ABSTRACT

Systems, devices, and methods for reducing Vpass disturb are provided. In one aspect, a semiconductor device includes a first deck and a second deck, each including memory cells coupled to corresponding word lines; and a peripheral circuit coupled to the memory array structure. For programming a first memory cell of the first deck, the peripheral circuit configured to: apply a first voltage to a first word line coupled to the first memory cell; apply a second voltage to a second word line of the first deck; apply a third voltage to a third word line between the first word line and a fourth word line of the second deck; and apply a fourth voltage to the fourth word line. The first voltage is greater than the second voltage, the second voltage is greater than the fourth voltage, and the fourth voltage is greater than the third voltage.

### CROSS-REFERENCE TO RELATED APPLICATIONS

This application is a continuation of International Application No. PCT/CN2024/140606, filed on Dec. 19, 2024, the disclosure of which is hereby incorporated by reference in its entirety.

### TECHNICAL FIELD

The present disclosure relates to semiconductor devices and fabrication processes for semiconductor devices.

### BACKGROUND

Semiconductor devices may be classified into non-volatile memory devices, such as flash memory devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

### SUMMARY

The present disclosure describes methods, devices, systems and techniques for programming semiconductor devices.

One aspect of the present disclosure features a semiconductor device, including: a memory array structure includes a first deck and a second deck, each includes a plurality of memory cells coupled to a corresponding plurality of word lines; and a peripheral circuit coupled to the memory array structure. For programming a first memory cell in the plurality of memory cells of the first deck, the peripheral circuit configured to: apply a first voltage to a first word line coupled to the first memory cell of the first deck; apply a second voltage to a second word line of the first deck; apply a third voltage to a third word line between the first word line of the first deck and a fourth word line of the second deck; and apply a fourth voltage to the fourth word line of the second deck. The first voltage is greater than the second voltage, the second voltage is greater than the fourth voltage, and the fourth voltage is greater than the third voltage.

In some implementations, the fourth word line is coupled to a second memory cell of the plurality of memory cells of the second deck, and the peripheral circuit is configured to program the first memory cell of the first deck before programming the second memory cell of the second deck.

In some implementations, for programming the second memory cell of the second deck, the peripheral circuit is configured to: apply a fifth voltage to the fourth word line coupled to the second memory cell of the second deck. The fifth voltage is greater than the second voltage; apply the second voltage to the first word line and the second word line, and after a predetermined time period, reduce the second voltage to a ninth voltage; apply an eleventh voltage to the third word line; and apply a tenth voltage to a fifth word line of the second deck.

In some implementations, the third voltage is smaller than the eleventh voltage.

In some implementations, the fourth voltage is smaller than the tenth voltage.

In some implementations, the third voltage is greater than or equal to 50% of the second voltage.

In some implementations, the fourth voltage is greater than or equal to 70% of the second voltage.

In some implementations, the peripheral circuit is configured to reduce the second voltage to the ninth voltage that is applied to the first word line and the second word line after applying the fifth voltage to the fourth word line.

In some implementations, the tenth voltage is different from the second voltage.

In some implementations, the memory array structure includes a third deck including a plurality of memory cells, the second deck is between the first deck and the third deck. For programming the first memory cell in the plurality of memory cells of the first deck, the peripheral circuit is further configured to apply the fourth voltage to a seventh word line of the third deck and a sixth word line between the fourth word line of the second deck and the seventh word line of the third deck.

In some implementations, programming the second memory cell in the plurality of memory cells of the second deck, the peripheral circuit is further configured to: apply the third voltage to the sixth word line; and apply the fourth voltage to the seventh word line.

In some implementations, the peripheral circuit is configured to program a third memory cell in the plurality of memory cells of the third deck after programming the second memory cell of the second deck. For programming the third memory cell in the plurality of memory cells of the third deck, the peripheral circuit is configured to: apply an eighth voltage to an eighth word line coupled to the third memory cell of the third deck. The eighth voltage is greater than the second voltage; apply the second voltage to the first word line, the second word line, the fourth word line, and the fifth word line, and after the predetermined time period, reduce the second voltage to the ninth voltage; apply the eleventh voltage to the sixth word line; and apply the tenth voltage to the seventh word line.

In some implementations, the third word line is a dummy word line.

In some implementations, the sixth word line is a dummy word line.

In some implementations, the first deck is coupled to a bit line, and the second deck is coupled to a source line.

Another aspect of the present disclosure features a method including: programming a plurality of memory cells in a first deck of the memory device; and programming a plurality of memory cells in a second deck of the memory device, Programming a first memory cell in the plurality of memory cells of the first deck includes: applying a first voltage to a first word line coupled to the first memory cell of the first deck; applying a second voltage to a second word line of the first deck; applying a third voltage to a third word line between the first word line of the first deck and a fourth word line of the second deck; and applying a fourth voltage to the fourth word line of the second deck. The first voltage is greater than the second voltage, the second voltage is greater than the fourth voltage, and the fourth voltage is greater than the third voltage.

In some implementations, programming a second memory cell in the plurality of memory cells of the second deck includes: applying a fifth voltage to the fourth word line coupled to the second memory cell of the second deck. The fifth voltage is greater than the second voltage; applying the second voltage to the first word line and the second word line, and after a predetermined time period, reducing the second voltage to a ninth voltage; applying an eleventh voltage to the third word line; and applying a tenth voltage to a fifth word line of the second deck, where the first memory cell of the first deck is programmed before programming the second memory cell of the second deck.

In some implementations, programming a plurality of memory cells in a third deck of the memory device, the second deck is between the first deck and the third deck. Programming the first memory cell in the plurality of memory cells of the first deck further includes applying the fourth voltage to a seventh word line of the third deck and a sixth word line between the fourth word line of the second deck and the seventh word line of the third deck.

In some implementations, programming the second memory cell in the plurality of memory cells of the second deck further includes: applying the third voltage to the sixth word line; and applying the fourth voltage to the seventh word line.

In some implementations, programming a third memory cell in the plurality of memory cells of the third deck includes: applying an eighth voltage to an eighth word line coupled to the third memory cell of the third deck. The eighth voltage is greater than the second voltage; applying the second voltage to the first word line, the second word line, the fourth word line, and the fifth word line, and after the predetermined time period, reducing the second voltage to the ninth voltage; applying the eleventh voltage to the sixth word line; and applying the tenth voltage to the seventh word line. The third memory cell of the third deck is programmed after programming the second memory cell of the second deck.

In some implementations, the third voltage is greater than or equal to 50% of the second voltage.

In some implementations, the third voltage is smaller than the eleventh voltage.

Another aspect of the present disclosure features a system including: a memory device and a memory controller coupled to the memory device and configured to operate the memory device. The memory device includes: a memory array structure includes a first deck and a second deck, each includes a plurality of memory cells coupled to a corresponding plurality of word lines; and a peripheral circuit coupled to the memory array structure. For programming a first memory cell in the plurality of memory cells of the first deck, the peripheral circuit is configured to: apply a first voltage to a first word line coupled to the first memory cell of the first deck; apply a second voltage to a second word line of the first deck; apply a third voltage to a third word line between the first word line of the first deck and a fourth word line of the second deck; and apply a fourth voltage to the fourth word line coupled to a second memory cell in the plurality of memory cells of the second deck. The first voltage is greater than the second voltage, the second voltage is greater than the fourth voltage, and the fourth voltage is greater than the third voltage, and where the peripheral circuit is configured to program the first memory cell of the first deck before programming the second memory cell of the second deck.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates a top-down view of an example memory device.

FIG. 1B illustrates a schematic diagram of the example memory device of FIG. 1A including a peripheral circuit.

FIG. 2 illustrates an example peripheral circuit of the example memory device of FIG. 1B.

FIG. 3A illustrates a cross-section view of NAND memory cells in the example memory device of FIG. 1A.

FIG. 3B illustrates a cross-section view of NAND memory cells in another example memory device.

FIG. 4 is a schematic diagram illustrating voltages applied to various word lines and channel potential distribution in an inhibit channel while programming a first memory cell of a first deck of a two-deck memory device.

FIG. 5 is a schematic diagram illustrating voltages applied to various word lines and channel potential distributions while programming a second memory cell of a second deck of the two-deck memory device of FIG. 4.

FIG. 6 is a schematic diagrams illustrating voltages applied to various word lines while programming a first deck of a three-deck memory device.

FIG. 7 is a schematic diagrams illustrating voltages applied to various word lines while programming a second deck of the three-deck memory device of FIG. 6.

FIG. 8 is a schematic diagrams illustrating voltages applied to various word lines while programming a third deck of the three-deck memory device of FIG. 6.

FIG. 9 illustrates a flow chart of an example process for programming a memory device.

FIG. 10 illustrates a block diagram of an example memory controller and an example memory device.

FIGS. 11A and 11B illustrate example storage products.

It is to be understood that the various exemplary implementations shown in the figures are merely illustrative representations and are not necessarily drawn to scale.

### DETAILED DESCRIPTION

A memory device, such as a flash memory chip, can apply a programming voltage to perform a programming operation to program a memory cell of the memory device. In some aspects, memory cells in a same memory bock of the memory device can share the same word line (WL) and can be programmed simultaneously. During the programming operation, a row decoder can select a WL associated with the memory cell to send a program voltage signal to program the memory cell into a target state. The unselected WLs in the memory block can be biased to a voltage level called “Vpass” to reduce the program disturbance on all unselected cells of the memory block.

An issue with programming a memory cell called “Vpass disturb” can occur when one or more unselected cells become inadvertently “soft-programed” as being associated with the unselected word lines. For example, during the programming operation, the Vpass voltage can be applied to the unselected word lines corresponding to the non-programmed cells of a programming string. At that time, the potential difference between the gate and the channel of the non-programmed cells can form an electric field. The magnitude of the electric field may not be large enough to allow electrons to easily enter a charge-trapping layer. However, due to the electric field, a certain probability for electrons to enter the charge-trapping layer may occur. This issue may worsen due to reduced thickness of interleaved gate layers and dielectric layers in a memory film stack with increased layers (e.g., in a NAND device). Accordingly, the non-programmed cells may be affected by the applied Vpass voltage, which is often called Vpass disturb. This can impose a challenge for L0 disturb, reducing the overall reliability of memory device.

Implementations of the present disclosure provide semiconductor devices and methods to reduce Vpass disturb. In some implementations, a memory device includes a memory array structure comprising a first deck and a second deck, each includes a plurality of memory cells coupled to a corresponding plurality of word lines. The memory device also includes a peripheral circuit coupled to the memory array structure. For programming a first memory cell in the plurality of memory cells of the first deck, the peripheral circuit can be configured to apply a first voltage to a first word line coupled to the first memory cell of the first deck, apply a second voltage to a second word line of the first deck; apply a third voltage to a third word line between the first word line of the first deck and a fourth word line of the second deck, and apply a fourth voltage to the fourth word line of the second deck. The first voltage is greater than the second voltage, the second voltage is greater than the fourth voltage, and the fourth voltage is greater than the third voltage.

Implementations of the present disclosure can provide one or more of the following technical advantages and/or benefits. The present disclosure can improve pass disturb and/or L0 disturb without sacrificing the boosting potential by a selected word line and without increasing manufacture cost. L0 disturb can occur when a memory cell that is in the L0 state (e.g., low threshold voltage state) is disturbed or inadvertently changed to a different threshold voltage state. This increases the reliability of memory device, especially those with decreased thickness of interleaved gate layers and dielectric layers in a high-density memory device (e.g., a three-dimensional (3D) NAND memory device).

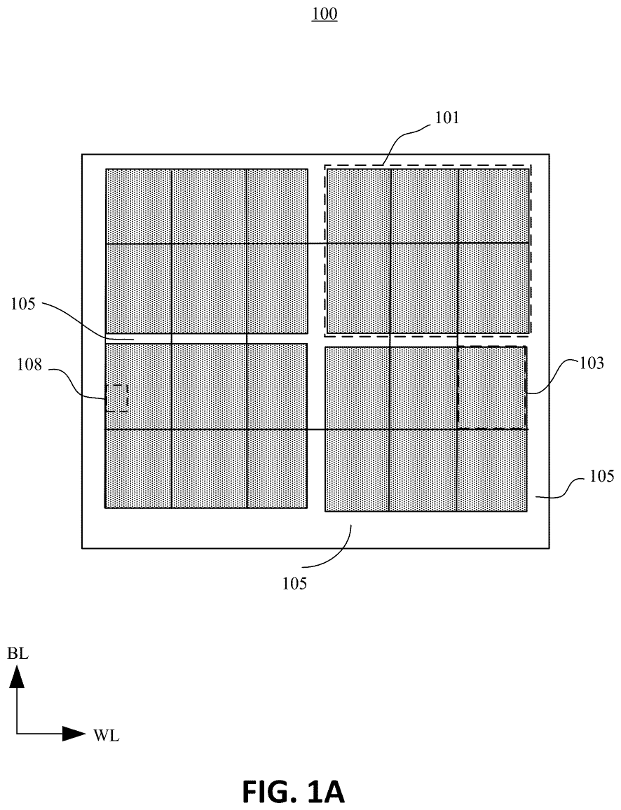

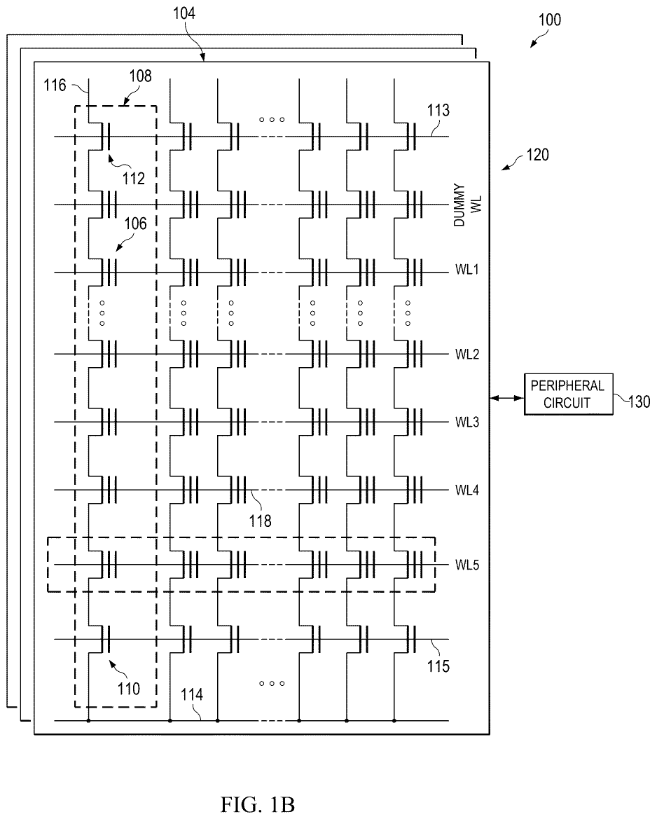

FIG. 1A illustrates a top-down view of a memory device 100, according to some implementations. The example configuration shown in FIG. 1A is given as a non-limiting example and it is to be appreciated that memory is scalable. In some implementations, memory device 100 can include one or more memory planes 101, each of which can include a plurality of memory blocks 103. Identical and concurrent operations can take place at each memory plane 101. Memory block 103, which can be megabytes (MB) in size, can be the smallest size to carry out erase operations. Memory die 100 can include, for example, four memory planes 101. Each memory plane 101 can include, for example, six memory blocks 103. Each memory block 103 can include a plurality of memory cells, where each memory cell can be addressed through interconnections such as bit lines and word lines. The bit lines and word lines can be laid out perpendicularly (e.g., in rows and columns, respectively), forming an array of metal lines. The direction of bit lines and word lines are labeled as “BL” and “WL” in FIG. 1A. In this disclosure, memory block 103 is also referred to as a “memory array,” “memory array structure” or “array.” The memory array is the core area in a memory device, performing storage functions.

In some implementations, memory device 100 also include a periphery region 105, an area surrounding memory planes 101. The periphery region 105 can include many digital, analog, and/or mixed-signal circuits to support functions of the memory array, for example, page buffers, a column decoder/bit line driver, a row decoder/word line driver, and sense amplifiers. Peripheral circuits use active and/or passive semiconductor devices, such as transistors, diodes, capacitors, resistors, etc., as would be apparent to a person of ordinary skill in the art.

In some implementations, the arrangement of the memory planes 101 in the memory device 100 and the arrangement of the memory blocks 103 in each memory plane 101 illustrated in FIG. 1A are only used as an example, which does not limit the scope of the present disclosure.

FIG. 1B illustrates a schematic diagram of the example memory device 100 including peripheral circuits, according to some implementations of the present disclosure. The example memory device 100 can be a three-dimensional (3D) NAND memory device. The memory device 100 can include a memory cell array 120 and peripheral circuits 130 coupled to the memory cell array 120. The memory cell array 120 can be a NAND flash memory cell array in which memory cells 106 are provided in the form of an array of NAND memory strings 108 each extending vertically above a substrate (not shown in FIG. 1B). In some implementations, each NAND memory string 108 includes a plurality of memory cells 106 coupled in series and stacked vertically. Each memory cell 106 can hold a continuous, analog value, such as an electrical voltage or charge that depends on the number of electrons trapped within a storage layer of the memory cell 106. The logic state (i.e., data) of each memory cell 106 in a memory block 104 can be determined based on the threshold voltage Vth of the memory cell 106. Each memory cell 106 can be a floating gate type memory cell including a floating-gate transistor, or a charge trap type memory cell including a charge-trap transistor.

In some implementations, each memory cell 106 is a single-level cell (SLC) with two possible memory states that can store one bit of data. For example, the first memory state “0” can correspond to a first range of voltages, and the second memory state “1” can correspond to a second range of voltages. In some implementations, each memory cell 106 is a multi-level cell (MLC) that is capable of storing more than one bit of data in more than two memory states. For example, the MLC can store two bits per cell, three bits per cell (also known as triple-level cell (TLC)), or four bits per cell (also known as a quad-level cell (QLC)). Each MLC can be programmed to support a range of possible nominal storage values. In one example, if each MLC stores two bits of data, then the MLC can be programmed to one of three possible programming levels from an erased state by writing one of three possible nominal storage values to the cell. A fourth nominal storage value can be used for the erased state.

As shown in FIG. 1B, each NAND memory string 108 can include a source select gate (SSG) 110 at its source end and a drain select gate (DSG) 112 at its drain end. The SSG 110 and the DSG 112 can be configured to activate selected NAND memory strings 108 (columns of the array) during read and program operations. In some implementations, the sources of NAND memory strings 108 in the same memory block 104 are coupled through a same source line (SL) 114, e.g., a common SL. In other words, NAND memory strings 108 in the same memory block 104 have an array common source (ACS), according to some implementations. The DSG 112 of each NAND memory string 108 is coupled to a respective bit line 116 from which data can be read or written via an output bus (not shown), according to some implementations. In some implementations, each NAND memory string 108 is configured to be selected or deselected by applying a select voltage (e.g., above the threshold voltage of the transistor having the DSG 112) or a deselect voltage (e.g., 0 V) to the respective DSG 112 through one or more DSG lines 113, and/or by applying a select voltage (e.g., above the threshold voltage of the transistor having the SSG 110) or a deselect voltage (e.g., 0 V) to the respective SSG 110 through one or more SSG lines 115.

As shown in FIG. 1B, NAND memory strings 108 can be organized into multiple memory blocks 104, each of which can have a common SL 114 coupled to the ACS. In some implementations, each memory block 104 can serve as a basic data unit for erase operations, such that memory cells 106 on the same memory block 104 are erased at the same time. To erase memory cells 106 in a selected memory block 104, the SL 114 coupled to the selected memory block 104 and unselected memory blocks in the same plane can be biased with an erase voltage. For example, the erase voltage can be a high positive voltage (e.g., 20 V or more). In some implementations, an erase operation can be performed at a half-block level, a quarter-block level, or a level having any suitable number of memory blocks or fractions of a memory block.

The memory cells 106 of adjacent NAND memory strings 108 can be coupled through word lines 118. The word line 118 can select which row of memory cells 106 is affected by read and program operations. Each word line 118 can include a gate line coupled to a plurality of control gates (gate electrodes) of a plurality of memory cells 106. Example word lines (e.g., WL 1, WL 2) shown in FIG. 1B are between one or more DSG lines 113 and one or more SSG lines 115.

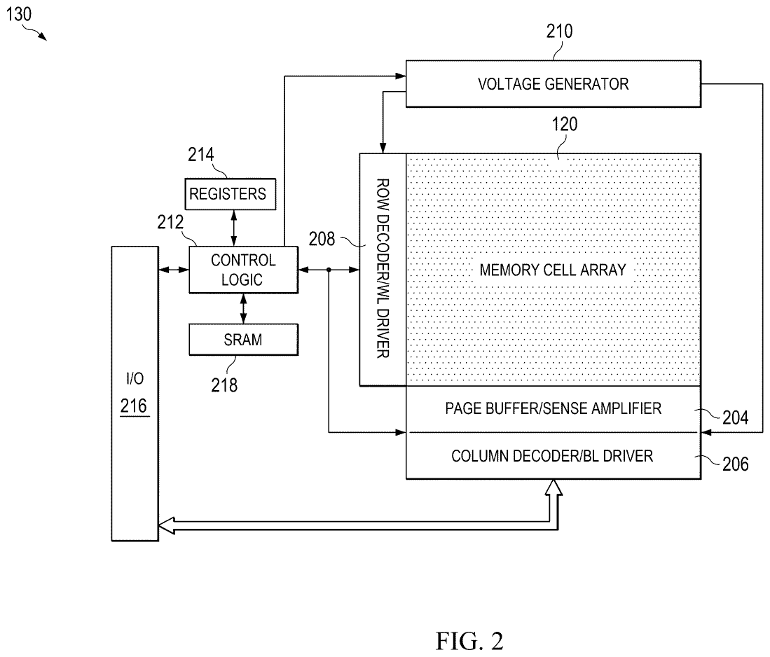

FIG. 2 illustrates the example peripheral circuit 130 of FIG. 1B, according to one or more aspects of the present disclosure. The peripheral circuits 130 can be coupled to the memory cell array 120 through bit lines 116, word lines 118, SLs 114, SSG lines 115, and DSG lines 113 (referring to FIG. 1B). The peripheral circuits 130 can include any suitable analog, digital, and mixed-signal circuits for facilitating the operations of the memory cell array 120 by applying and sensing voltage signals and/or current signals to and from each target memory cell 106 through bit lines 116, word lines 118, SLs 114, SSG lines 115, and DSG lines 113. The peripheral circuits 130 can include various types of peripheral circuits formed using metal-oxide-semiconductor (MOS) technologies. The example peripheral circuits 130 include a page buffer/sense amplifier 204, a column decoder/bit line driver 206, a row decoder/word line driver 208, a voltage generator 210, control logic 212, registers 214, an input/output (I/O) interface 216, a static random-access memory (SRAM) 218, and a data bus. In some examples, additional peripheral circuits not shown in FIG. 2 may be included as well.

The page buffer/sense amplifier 204 can be configured to read and program (write) data from and to memory cell array 120 according to the control signals from control logic 212. In another example, the page buffer/sense amplifier 204 may perform program verify operations to ensure that the data have been properly programmed into memory cells 106 coupled to selected word lines 118. In still another example, the page buffer/sense amplifier 204 may also sense the low power signals from the bit line 116 that represents a data bit stored in memory cell 106, and amplify the small voltage swing to recognizable logic levels in a read operation. The column decoder/bit line driver 206 can be configured to be controlled by the control logic 212 and select one or more NAND memory strings 108 by applying bit line voltages generated from the voltage generator 210.

The row decoder/word line driver 208 can be configured to be controlled by the control logic 212 and select/deselect memory blocks 104 of the memory cell array 120 and select/deselect word lines 118 of the memory block 104. The row decoder/word line driver 208 can be further configured to drive word lines 118 using word line voltages generated from the voltage generator 210. In some implementations, the row decoder/word line driver 208 can also select/deselect and drive SSG lines 115 and DSG lines 113. As described below in detail, the row decoder/word line driver 208 is configured to apply a program voltage to selected word line 118 in a program operation on memory cell 106 coupled to a selected word line 118.

The voltage generator 210 can be configured to be controlled by the control logic 212 and generate the word line voltages (e.g., read voltage, program voltage, pass voltage, local voltage, verify voltage, etc.), bit line voltages, and source line voltages to be supplied to the memory cell array 120.

The control logic 212 can be coupled to each peripheral circuit described above and configured to control operations of each peripheral circuit. The registers 214 can be coupled to the control logic 212 and include status registers, command registers, and address registers for storing status information, command operation codes (OP codes), and command addresses for controlling the operations of each peripheral circuit.

The I/O interface 216 can be coupled to the control logic 212 and act as a control buffer to buffer and relay control commands received from a memory controller to the control logic 212 and status information received from the control logic 212 to the memory controller. The I/O interface 216 can also be coupled to the column decoder/bit line driver 206 via a data bus, and act as a data input/output (I/O) interface and a data buffer to buffer and relay data to and from the memory cell array 120.

The SRAM 218 can be coupled to the control logic 212 and be configured to store operation setting information. In some implementations, the peripheral circuit (e.g., the control logic 212) can be configured to obtain the operation setting information from memory cell array 120 (e.g., from a configure block in the memory cell array 120) and store the operation setting information in the SRAM 218.

The operation setting information can vary based on the types of operation. In some cases, the types of operation can include, but are not limited to, SLC operation, MLC operation, TLC operation, QLC operation, and PLC operation. The operation can be, for example, a write operation or a read operation. So, for example, the operation setting information of TLC operation can be different from the operation setting information of QLC operation. The operation setting information for a write operation can differ from that for a read operation, even within the same type of operation.

In some cases, the operation setting information includes at least one of voltage control information, timing control information, or process control information. Taking the QLC writing operation as an example, the voltage control information can include at least one of word line bias source, selected word line voltage, unselected word line voltage, special word line voltage, voltages in the page buffer controlling the bit lines, or other suitable voltage control information. The timing control information can include timing control information associated with controlling the word lines and/or bit lines, such as width pulses of programming, verification sensing time, or other suitable timing control information. The process control information can include the process control information associated with the start of each state verification, the start of unselect string boosting enhancement (USBE), or other suitable process control information.

In some implementations, the operation setting information of a type of operation can include a plurality of parameters and their corresponding parameter vales. For example, the operation setting information of a type of operation can include one or more voltage control parameters, one or more timing control parameters, and/or one or more process control parameters, and their corresponding parameter values. In some cases, the difference in operation setting information between two types of operation can be due to at least one different parameter, different parameter values for at least one parameter, or both.

According to the operation setting information in the SRAM 218, the peripheral circuit can be configured to perform an operation corresponding to a type of operation on the memory cell array. For example, the peripheral circuit can perform a write or a read operation corresponding to a type of operation (e.g., SLC operation, MLC operation, TLC operation, QLC operation, or PLC operation) on the memory cell array using at least one of voltage control information, timing control information, or process control information in the operation setting information corresponding to the type of operation.

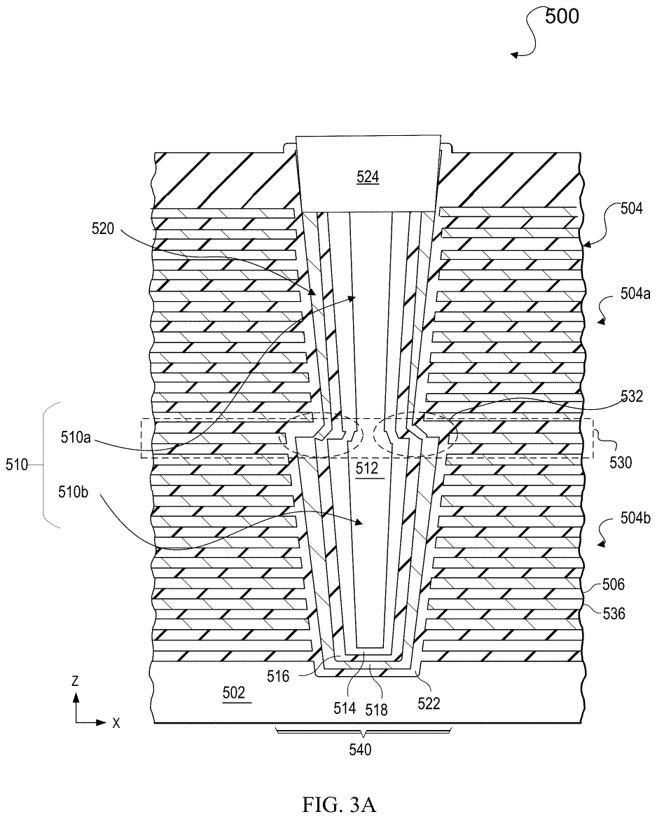

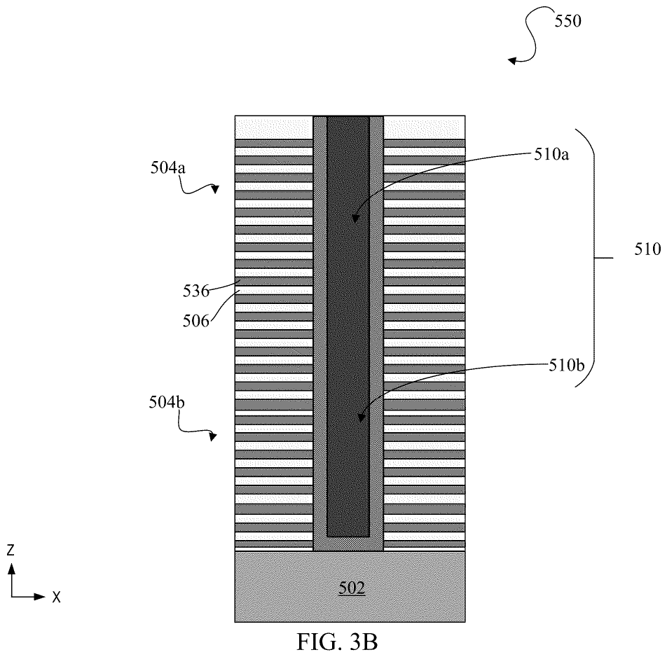

FIG. 3A illustrates a cross-section view of NAND memory cells in a memory device. The memory device 500 may include a substrate 502, which is a doped semiconductor layer and may include silicon (e.g., single crystalline silicon), silicon germanium (SiGe), gallium arsenide (GaAs), germanium (Ge), silicon on insulator (SOI), germanium on insulator (GOI), or any other suitable materials. In some implementations, substrate 502 is a thinned substrate (e.g., a semiconductor layer), which is thinned by grinding, etching, chemical mechanical polishing (CMP), or is formed by depositing a doped semiconductor layer, or any combination thereof. Substrate 502 of memory device 500 includes two surfaces (e.g., a top surface and a bottom surface) extending laterally in the x-direction (i.e., the lateral direction). As used herein, whether one component (e.g., a layer or a device) is “on,” “above, ” or “below” another component (e.g., a layer or a device) of a 3D memory device (e.g., memory device 500) is determined relative to the substrate of the 3D memory device (e.g., substrate 502) in the y-direction (i.e., the vertical direction) when the substrate is positioned in the lowest plane of the 3D memory device in the y-direction.

In some implementations, memory device 500 is a 3D NAND Flash memory device in which memory cells 520 are provided in the form of an array of NAND memory strings each extending vertically above substrate 502.

As shown in FIG. 3A, memory device 500 may include a stack structure 504 with interleaved gate lines 536 (also called word lines 536 in the present disclosure) and first dielectric layers 506. The gate lines 536 may include conductive materials including, but not limited to, tungsten (W), cobalt (Co), copper (Cu), aluminum (Al), polysilicon, doped silicon, silicides, or any combination thereof. First dielectric layers 506 may include dielectric materials including, but not limited to, silicon oxide, silicon nitride, silicon oxynitride, or any combination thereof.

A select gate (SG) layer can be formed on top of the stack structure 504 which is isolated from the gate lines 536. The select gate layer can comprise the same conductive material as the gate lines. For example, the select gate layer can be the top one or more conductive layers in the stack structure 504. Alternatively, the select gate layer can comprise a different conductive material compared to the gate lines. For example, the select gate layer can comprise doped polysilicon while the gate lines can comprise Tungsten (W). The NAND memory string may include one or more channel structures 510 extending vertically through both the stack structure 504 and the select gate layer in the y-direction. In some implementations, an additional dielectric layer is formed between the select gate layer and the stack structure 504.

Channel structures 510 may include a channel hole or a channel trench with a layered structure 540. In some implementations, the remaining space of channel structure 510 may be partially or fully filled with a filling layer 512 including dielectric materials, such as silicon oxide. In some implementations, the layered structure 540 comprises a blocking layer, a charge trapping layer (also called storage layer in some cases), a dielectric layer (also called a tunneling layer in some cases), and a semiconductor channel layer. The semiconductor channel layer 514 is in contact with and laterally surrounded by the dielectric layer 516. The dielectric layer 516 is in contact with and laterally surrounded by the charge trapping layer 518. The charge trapping layer 518 is in contact with and laterally surrounded by the blocking layer 522. In other words, the filling layer 512, semiconductor channel layer 514, dielectric layer 516, charge trapping layer 518, and blocking layer 522 can be arranged radially from the center toward the outer surface of the channel structure 510 in this order. The semiconductor channel layer 514 can include doped polysilicon or silicon germanium (SiGe). The dopants can be N type dopants (e.g., Phosphorus (P) or Arsenic (As)) or P type dopants (e.g., Boron (B) or Gallium (Ga)) at a desired doping level. Dielectric layer 516 may include silicon oxide, silicon oxynitride, or any combination thereof. Charge trapping layer 518 may include silicon nitride, silicon oxynitride, silicon, or any combination thereof. Blocking layer 522 may include silicon oxide, silicon oxynitride, high dielectric constant (high-k) dielectrics, or any combination thereof. In one example, the layered structure 540 can include silicon oxide/silicon oxynitride (or silicon nitride)/silicon oxide/polysilicon (ONOP), for the blocking layer 522, the charge trapping layer 518, the dielectric layer 516, and the semiconductor channel layer 514, respectively.

In some implementations, channel structure 510 may further include a semiconductor plug in a lower portion (e.g., at the lower end) of channel structure 510 (not shown). As used herein, the “upper end” and/or “top end” of a component (e.g., channel structure 510) is the end farther away from substrate 502 in the positive z-direction, and the “lower end” and/or “bottom end” of the component (e.g., channel structure 510) is the end closer to substrate 502 in the negative z-direction. The semiconductor plug may include a semiconductor material, such as silicon, which is epitaxially grown from substrate 502 in any suitable directions. It is understood that in some implementations, the semiconductor plug includes single crystalline silicon, the same material as substrate 502. In other words, the semiconductor plug may include an epitaxially-grown semiconductor layer that is the same as the material of substrate 502. In some implementations, part of the semiconductor plug is above the top surface of substrate 502 and in contact with semiconductor channel layer 514. The semiconductor plug may function as a channel controlled by a source select gate of the NAND memory string. It is understood that in some implementations, memory device 500 does not include the semiconductor plug, as shown in FIG. 3A.

In some implementations, channel structure 510 further includes a channel plug 524 in an upper portion (e.g., at the upper end) of channel structure 510, which can be stacked over the layered structure 540. Channel plug 524 may be in contact with the upper end of semiconductor channel layer 514 of the layered structure 540. In some implementations, the channel plug 524 material can include, but not limited to, TiN, TaN, Al, W, Cu, doped-polysilicon, silicides, or any combination thereof. By covering the upper end of channel structure 510 during the fabrication of memory device 500, channel plug 524 may function as an etch stop layer to prevent etching of dielectrics filled in channel structure 510, such as silicon oxide and silicon nitride. In some implementations, channel plug 524 functions as the drain of the NAND memory string. Channel plug 524 may also increase contact area for the landing of a channel contact (not shown).

In some implementations, each gate line 536 in stack structure 504 (e.g., a memory stack) functions as a gate conductor of memory cells in the NAND memory string. Gate lines 536 may extend laterally coupling a plurality of memory cells. In some implementations, memory cells in NAND memory string include semiconductor channel layer 514, memory film (including dielectric layer 516, charge trapping layer 518, and blocking layer 522), and the gate lines 536. The gate lines 536 may further include a gate conductor made from tungsten, adhesion layers including titanium/titanium nitride (Ti/TiN) or tantalum/tantalum nitride (Ta/TaN), and gate dielectric layers made from high-k dielectric materials. The gate lines 536 can be used to control the transistors in memory cells.

In some implementations, as shown in FIG. 3A, the memory array structure of the memory device 500 includes two decks, an upper deck 504a and a lower deck 504b. Each deck has a plurality of NAND memory cells 520. The channel structure 510 may be formed by stacking more than one channel sub-structures. As shown in FIG. 3A, two channel sub-structures are stacked along z-direction, e.g., an upper channel sub-structure 510a and a lower channel sub-structure 510b.

In some implementations, due to the etching characteristics, the bottom end of the upper channel sub-structure 510a has a smaller size along x-direction than the top end of the lower channel sub-structure 510b, as illustrated in FIG. 3A. In some implementations, the memory array structure of the memory device 500 includes one or more memory cells 530 near the interface of the upper deck 504a and the lower deck 504b. In some implementations, the memory cell 530 that is near the interface of the upper deck 504a and the lower deck 504b is a dummy memory cell and does not store user data. The gate line 536 (also called word line 536 in the present disclosure) coupled to the dummy memory cell can be referred to as a dummy word line in this disclosure. It is to be understood that memory device 500 can include one or more dummy word lines near the interface of the upper deck 504a and the lower deck 504b. These dummy word lines can be positioned in the upper deck 504a, in the lower deck 504b, or both.

In some implementations, the lower deck 504b and the upper deck 504a are formed sequentially on the same substrate 502 with two separate etching of channel holes through the film stack structure 504. In some implementations, the lower deck 504b is manufactured on a first substrate, and the upper deck 504a is manufactured on a second substrate. The upper deck 504a and the lower deck 504b can be stacked together through hybrid bonding (not shown in FIG. 3A) after the substrate of the upper deck 504a is thinned or removed. A hybrid bonding can include a combination of metal-to-metal bonding and a direct oxide bonding. For example, each structure can include bonding contacts at the bonding interface. The upper deck 504a and the lower deck 504b can be stacked together by integrating corresponding bonding contacts at the bonding interface (not shown in FIG. 3A). In some implementations, the memory array structure of the memory device 500 includes a connection structure (not shown in FIG. 3A) between the upper deck 504a and the lower deck 504b. The connection structure can include a polysilicon layer.

In some implementations, as opposed to two channel sub-structures 510a, 510 b of FIG. 3A, the channel structure 510 is a continuous channel structure 510, as illustrated in FIG. 3B. The upper deck 504a can refer to the upper portion of a memory array structure of the memory device 550 that includes the upper portion 510a of the channel structure 510, while the lower deck 504b can refer to the lower portion of the memory array structure that includes the lower portion 510b of the channel structure 510. In such implementations, the bottom end of the upper portion 510a of the channel structure 510 can have a size identical to or substantially similar to that of the top end of the lower portion 510b of the channel structure 510, as illustrated in FIG. 3B.

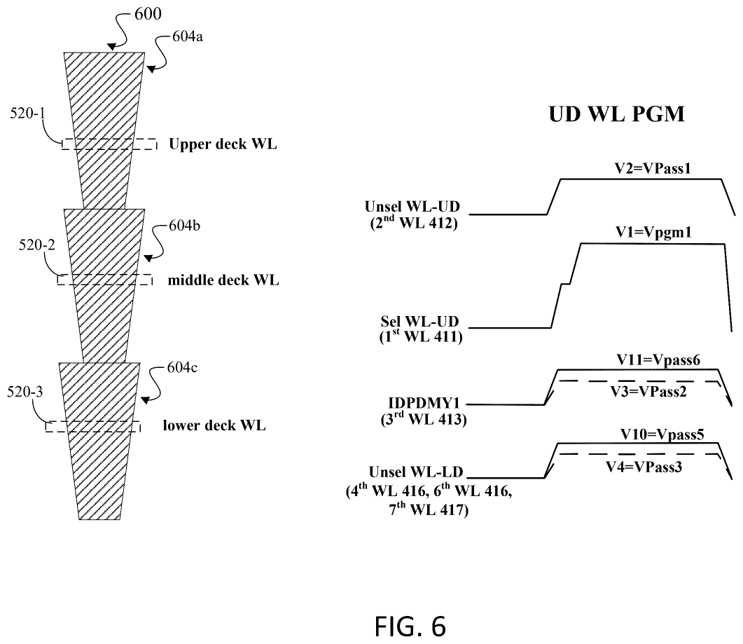

It is to be understood that more than two decks can be stacked together along Z direction to increase the memory storage density. For example, three decks can be stacked together along Z direction, as illustrated below in FIG. 6. It is further to be understood that the channel structure 510 may have other shapes (e.g., elliptical cylinder or irregular shape).

In some implementations, a semiconductor device 500,550 can include at least one array die that has the memory array structure discussed above in reference to FIGS. 3A and 3B and at least one CMOS die (not shown). The array die and the CMOS die can be stacked and bonded together, e.g., through hybrid bonding. A hybrid bonding can include a combination of metal-to-metal bonding and a direct oxide bonding. In some implementations, the array die includes one or more first conductive contacts isolated by a first dielectric material. The CMOS die includes one or more second conductive contacts isolated by a second dielectric material. The first conductive contacts can be in contact with the one or more second conductive contacts to form hybrid bonding between the array die and the CMOS die.

In some implementations, a CMOS die is respectively coupled to one of the multiple array dies. In some implementations, a CMOS die can be coupled to two or more array dies and drive the two or more array dies to operate in the same or similar manner.

In some implementations, the CMOS die includes peripheral circuits on and/or in a substrate for controlling memory operations (e.g., read or write) of memory cells 520 in the array die. In some implementations, the peripheral circuits include a plurality of transistors (e.g., planar transistors and/or 3D transistors). Trench isolations (e.g., shallow trench isolations (STIs)) and doped regions (e.g., wells, sources, and drains of transistors) can be formed on or in the substrate as well. In some examples, the peripheral circuits are formed using complementary metal-oxide-semiconductor (CMOS) technology.

In some implementations, the CMOS die includes an interconnect layer above the peripheral circuits to transfer electrical signals to and from the peripheral circuits. The interconnect layer can include a plurality of interconnects (also referred to herein as “contacts”), including lateral interconnect lines and VIA contacts. The interconnect layer can further include one or more interlay dielectric (ILD) layers in which the interconnect lines and via contacts can form. That is, the interconnect layer can include interconnect lines and via contacts in multiple ILD layers. In some implementations, peripheral circuits are coupled to one another through the interconnects in the interconnect layer. The interconnects in interconnect layer can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some examples, the semiconductor device 500, 550 includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer through hybrid bonding. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

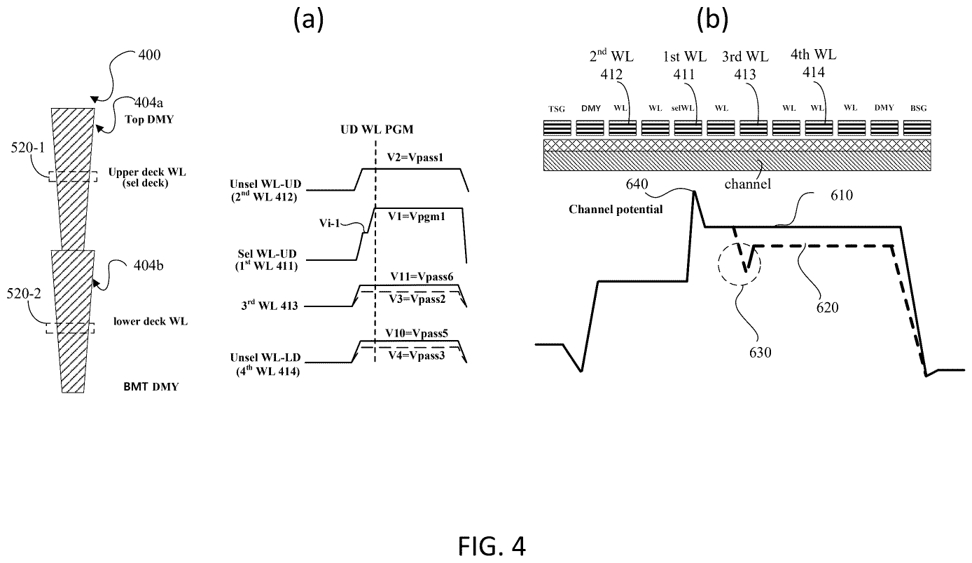

FIG. 4 is a schematic diagram illustrating voltages applied to various word lines (diagram (a)) and channel potential distribution in an inhibit channel (diagram (b)) while programming a first memory cell of a first deck of a two-deck memory device 400. The two-deck memory device 400 can be implemented as the memory device 500 of FIG. 3A or the memory device 550 of FIG. 3B.

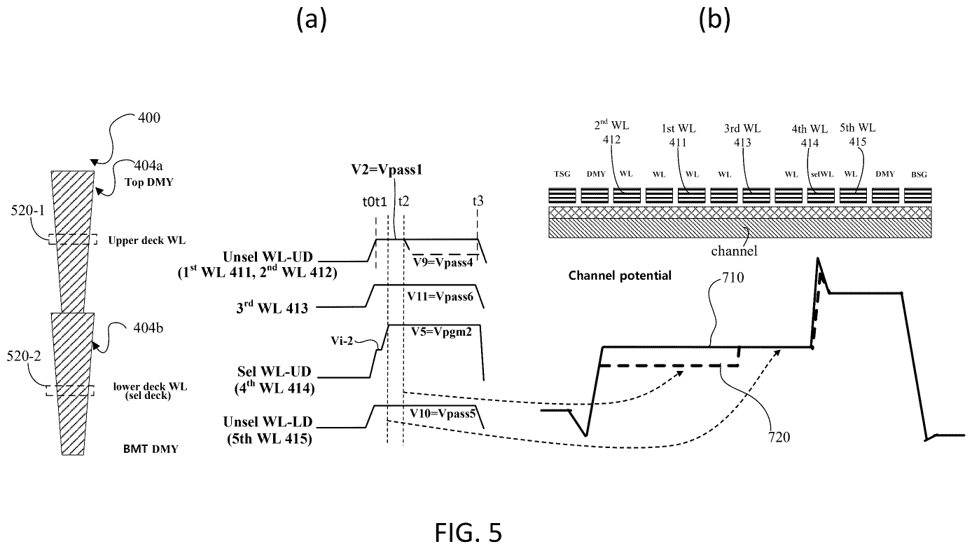

It is to be noted that for a two-deck memory device 400, the first deck in the present disclosure can refer to the deck that is programmed first, and the second deck can refer to the deck that is programmed after the first deck. Therefore, if the peripheral circuit 130 is configured to program the memory string from the upper deck to the lower deck, the first deck can be the upper deck 504a of FIGS. 3A-3B, or the upper deck 404a of FIG. 4, while the second deck can be the lower deck 504b of FIGS. 3A-3B, or the lower deck 404b of FIG. 4. In contrast, if the peripheral circuit 130 is configured to program the memory string from the lower deck to the upper deck, then the first deck can be the lower deck 504b of FIGS. 3A-3B, or the lower deck 404b of FIG. 4, while the second deck can be the upper deck 504a of FIGS. 3A-3B, or the upper deck 404a of FIG. 4. In the present example, the two-deck memory device 400 in FIGS. 4-5 is configured to be programmed from the upper deck 404a to the lower deck 404b. Therefore, in the description below in reference to FIGS. 4-5, the first deck can refer to the upper deck 404a, while the second deck can refer to the lower deck 404b.

As illustrated in diagram (a) of FIG. 4, for programming a first memory cell 520-1 in the plurality of memory cells of the first deck 404a, the peripheral circuit 130 is configured to apply a first program voltage Vpgm1 to a first word line (WL) 411 of the first deck 404a, where the first word line 411 is coupled to the first memory cell 520-1 of the first deck 404a. In some implementations, applying Vpgm1 to the first word line 411 includes two steps: first, the voltage can be ramped up to a first intermediate voltage Vi-1, and then further increased to the first program voltage Vpgm1. The first program voltage Vpgm1 is also referred to as the first voltage V1 in the present disclosure.

It is to be noted that in the present disclosure, when a memory cell coupled to a word line is being programmed, the word line can be referred to as a selected word line; if it is not being programmed (either because it is already programmed or in an erase state), the word line can be referred to as an unselected word line. For example, the first word line 411 can be called a selected word line of the first deck 404a when it is being programmed, while the first word line 411 can be called an unselected word line of the first deck 404a when it is not being programmed.

In some implementations, for programming the first memory cell 520-1 of the first deck 404a, the peripheral circuit 130 is further configured to (1) apply a first pass voltage Vpass1 to an unselected word line (e.g., second word line 412 of FIG. 4) of the first deck 404a; (2) apply a second pass voltage Vpass2 to an unselected word line (e.g., third word line 413 of FIG. 4) between the first word line 411 of the first deck 404a and a fourth word line 414 of the second deck 404b; and (3) apply a third pass voltage Vpass3 to an unselected word line (e.g., fourth word line 414 of FIG. 4) of the second deck 404b. In some implementations, the fourth word line 414 is coupled to a second memory cell 520-2 of the plurality of memory cells of the second deck 404b, and the peripheral circuit 130 is configured to program the first memory cell 520-1 of the first deck 404a before programming the second memory cell 520-2 of the second deck 404b.

In some implementations, the program voltage Vpgm1 is higher than all pass voltages Vpass1, Vpass2 and Vpass3. The first pass voltage Vpass1 is greater than the third pass voltage Vpass3, and the third pass voltage Vpass3 is greater than the second pass voltage Vpass2. In some implementations, the second pass voltage Vpass2 is greater than or equal to 50% of the first pass voltage Vpass1. In some implementations, the third pass voltage Vpass3 is greater than or equal to 70% of the first pass voltage Vpass1. It is to be noted that, in the present disclosure, the first pass voltage Vpass1 can be referred to as the second voltage V2, the second pass voltage Vpass2 can be referred to as the third voltage V3, the third pass voltage Vpass3 can be referred to as the fourth voltage V4.

In some implementations, the third word line 413 is a dummy word line coupled to a dummy memory cell that does not store user data. In some implementations, the third word line 413 is positioned near the interface of the first deck 404a and the second deck 404b. In some implementations, the third word line 413 is in the first deck 404a. In some implementations, the third word line 413 is in the second deck 404b. In some implementations, the third word line 413 is an active word line coupled to a memory cell that is configured to store user data.

In some implementations, the memory device 400 includes two or more dummy word lines near the interface between the first deck 404a and the second deck 404b, and the two or more dummy word lines includes the third word line 413. In some implementations, the two or more dummy word lines are all in the first deck 404a. In some implementations, the two or more dummy word lines are all in the second deck 404b. In some implementations, some dummy word lines are in the first deck 404a, and other dummy word lines are in the second deck 404b. In some implementations, the two or more dummy word lines are applied with the same voltages (e.g., Vpass2) when programming the first memory cell in the first deck 404a.

In some implementations, the two or more dummy word lines are applied with different voltages. For example, the first deck 404a may include one or more dummy word lines, and the second deck 404b may also include one or more dummy word lines. The word line from each deck that is closest to the interface between the first deck 404a and the second deck 404b can be applied with Vpass2, but the dummy word lines that are farther away from the interface can be applied with a voltage greater than Vpass2. In some implementations, the voltages that are applied to the dummy word lines gradually increase as the dummy word lines move further from the interface between the first deck 404a and the second deck 404b, when programming the first memory cell of the first deck 404a.

Diagram (b) of FIG. 4 illustrate a simplified diagram of channel potential distribution at different locations of a memory string. Two channel potential distributions are shown, e.g., the first distribution 610 and the second distribution 620. The first distribution 610 can refer to the channel potential distribution when all unselected word lines are applied with the first pass voltage Vpass1. In contrast, the second distribution 620 can refer to the channel potential distribution when different pass voltages are applied to various word lines, as shown in diagram (a) of FIG. 4.

In the present example illustrated in FIG. 4, the memory device 400 is configured to program the first deck 404a (e.g., the upper deck) first, and thus when programming the first memory cell 520-1 of the first deck 404a, without limiting to any particular theory, the second deck 404b (e.g., the lower deck) can be in ease state and have a higher channel potential compared to the programmed states. Because the third word line 413 that is between the selected word line of the first deck 404a and unselected word line(s) of the second deck 404b is applied with the lowest pass voltage Vpass2 (that is, lower than Vpgm1, Vpass1 and Vpass3), a “soft cut” 630 of channel potential can be present. That means, the channel potential can have a dip near the third word line 413. Such “soft-cut” potential variation can reduce the impact of lower pass voltages (e.g., Vpass3) on the boosting potential 640 near the selected word line, while still providing the advantage of reducing pass disturb with lower pass voltages. The method to create a soft-cut in the channel potential distribution can be referred to as a soft-cut process in the present configuration.

FIG. 5 is a schematic diagram illustrating voltages applied to various word lines (diagram (a)) and channel potential distributions (diagram (b)) while programming a second memory cell 520-2 of the second deck 404b of two-deck memory device 400. As described above, the second deck 404b can refer to the lower deck of the memory device 400.

In some implementations, for programming a second memory cell 520-2 of the second deck 404b, the peripheral circuit 130 is configured to apply a second program voltage Vpgm2 to the fourth word line 414 of the second deck 404b, where the fourth word line 414 is coupled to the second memory cell 520-2 of the second deck 404b. The fourth word line 414 can be referred to as a selected word line of the second deck 404b when it is being programmed in the present disclosure. The second program voltage Vpgm2 can be greater than the first pass voltage Vpass1. The second program voltage Vpgm2 can be identical to or different from the first program voltage Vpgm1. The second program voltage Vpgm2 can also be referred to as a fifth voltage V5 in the present disclosure.

In some implementations, for programming the second memory cell 520-2 of the second deck 404b, the peripheral circuit 130 is further configured to (1) apply the first pass voltage Vpass1 to unselected word lines of the first deck 404a (e.g., the first word line 411 and the second word line 412 of the first deck 404a), and after a predetermined time period, reduce the first pass voltage Vpass1 to a fourth pass voltage Vpass4 (also called a ninth voltage in the present disclosure) on these unselected word lines; and (2) apply a sixth pass voltage Vpass6 (also called an eleventh voltage in the present disclosure) to the third word line 413 between the first word line 411 of the first deck 404a and the fourth word line 414 of the second deck 404b; (3) apply a fifth pass voltage Vpass5 (also called a tenth voltage in the present disclosure) to the unselected word line of the second deck 404b (e.g., a fifth word line 415). For example, as illustrated in diagram (a) of FIG. 5, the first pass voltage Vpass1 can be applied to unselected word lines of the first deck 404a at time t0. After a predetermined period of time, Vpass1 can be reduced to Vpass4 at time t2, which can be maintained until the program phase concludes at time t3. The predetermined time period can be the time period between t0 and t2. In contrast, the third word line 413 and the unselected word line of the second deck 404b (e.g., the fifth word line 415) can hold its respective pass voltage (e.g., Vpass6, Vpass5) until the end of the program phase.

In some implementations, the second pass voltage Vpass2 is smaller than the sixth pass voltage Vpass6. In some implementations, the third pass voltage Vpass3 is smaller than the fifth pass voltage Vpass5. In some implementations, the second pass voltage Vpass2 is smaller than the third pass voltage Vpass3. In some implementations, the fifth pass voltage Vpass5 is different from the first pass voltage Vpass1. In some implementations, the sixth pass voltage Vpass6 is different from the first pass voltage Vpass1. In some implementations, the fifth pass voltage Vpass5 is different from the sixth pass voltage Vpass6. In some implementations, the sixth pass voltage Vpass6 is greater than or equal to the fifth pass voltage Vpass5. In some implementations, the first pass voltage Vpass1, the fifth pass voltage Vpass5 and the sixth pass voltage Vpass6 are the same.

In some implementations, the peripheral circuit 130 is configured to reduce the first pass voltage Vpass1 to the fourth pass voltage Vpass4 that is applied to the first word line 411 and the second word line 412 after applying Vpgm2 to the fourth word line 414. In some implementations, applying Vpgm2 to the fourth word line 414 includes two steps: first, the voltage can be ramped up to a second intermediate voltage Vi-2, and then further increased to the second program voltage Vpgm2. The voltage reduction on the unselected word lines of the first deck 404a (e.g., the first word line 411 and the second word line 412) can be performed after the selected word line of the second deck 404b (e.g., the fourth word line 414) reaches Vpgm2. In some implementations, the peripheral circuit 130 is configured to reduce the first pass voltage Vpass1 to the fourth pass voltage Vpass4 that is applied to the first word line 411 and the second word line 412 before the program phase concludes at time t3. In some implementations, the predetermined time is shorter than a time period between t0 and t3.

Diagram (b) of FIG. 5 illustrate a simplified diagram of channel potential distribution at different locations of a memory string. Two channel potential distributions are illustrated, the first distribution 710 and the second distribution 720. The first distribution 710 can refer to the channel potential distribution at time t1, whereas the second distribution 720 can refer to the channel potential distribution at time t2. Without limiting to any particular theory, when programming the second deck 404b, the first deck 404a is in a programmed state with a lower channel potential. To reduce Vpass4 impact on the boosting potential by the selected word line, a two-step process can be deployed: first, the first pass voltage Vpass1 is applied to the unselected word lines coupled to memory cells that are already programmed; after the program voltage is fully ramped up and/or the channel potential is substantially boosted by the selected word line, the first pass voltage Vpass1 is then lowered to the fourth pass voltage Vpass4 to reduce pass disturb, as described above. This two-step process can reduce the impact of lower pass voltages (e.g., Vpass4) on the boosting potential 640 by the selected word line, while still providing the advantage of reducing pass disturb with lower pass voltages.

FIGS. 6-8 are schematic diagrams illustrating voltages applied to various word lines while programming different decks of a three-deck memory device 600. Specifically, FIG. 6 is a schematic diagram illustrating voltages applied to various word lines while programming the first deck 404a of a three-deck memory device 600.

The memory device 600 can include three decks, e.g., the upper deck 604a, the middle deck 604b, and the lower deck 604c. In some implementations, the memory device 600 is configured to first program at least one memory cell of the upper deck 604a, then program at least one memory cell of the middle deck 604b, and finally program at least one memory cell of the lower deck 604c. Therefore, the upper deck 604a of the memory device 600 can be referred to as the first deck 604a, the middle deck 604b of the memory device 600 can be referred to as the second deck 604b, and the lower deck 604c of the memory device 600 can be referred to as the third deck 604c. The first deck 604a of the memory device 600 can be identical or similar to the first deck 404a of the memory device 400 of FIGS. 4 and 5. The second deck 604b of the memory device 600 can be identical or similar to the second deck 404b of the memory device 400 of FIGS. 4 and 5. In some implementations, the first deck 604a is coupled to a bit line, and the third deck 604c is coupled to a source line.

In some implementations, for programming the first memory cell 520-1 of the first deck 604a of the 3-deck memory device 600, the peripheral circuit 130 is configured to (1) apply the first program voltage Vpgm1 to the first word line 411 of the first deck 604a, where the first word line 411 is coupled to the first memory cell 520-1 of the first deck 604a; (2) apply the first pass voltage Vpass1 to an unselected word line of the first deck 604a (e.g., the second word line 412); (3) apply the second pass voltage Vpass2 to an unselected word line (e.g., the third word line 413) between the selected word line (e.g., the first word line 411) of the first deck 604a and an unselected word line (e.g., the fourth word line 414) of the second deck 604b; and (4) apply a third pass voltage Vpass3 to (i) an unselected word line (e.g., the fourth word line 414) of the second deck 604b, (ii) to an unselected word line (e.g., a sixth word line 416) that is between the fourth word line 414 of the second deck 604b and a seventh word line 417 of the third deck 604c, and (iii) to an unselected word line (e.g., the seventh word line 417) of the third deck 604c.

In some implementations, the sixth word line 416 is a dummy word line coupled to a dummy memory cell that does not store user data. In some implementations, the sixth word line 416 is positioned near the interface between the second deck 604b and the third deck 604c. In some implementations, the sixth word line 416 is in the second deck 604b. In some implementations, the sixth word line 416 is in the third deck 604c. In some implementations, the sixth word line 416 is an active word line coupled to a memory cell that is configured to store user data.

In some implementations, the program voltage Vpgm1 is higher than all pass voltages Vpass1, Vpass2 and Vpass3. The first pass voltage Vpass1 is greater than the third pass voltage Vpass3, and the third pass voltage Vpass3 is greater than the second pass voltage Vpass2. In some implementations, the second pass voltage Vpass2 is greater than or equal to 50% of the first pass voltage Vpass1. In some implementations, the third pass voltage Vpass3 is greater than or equal to 70% of the first pass voltage Vpass1.

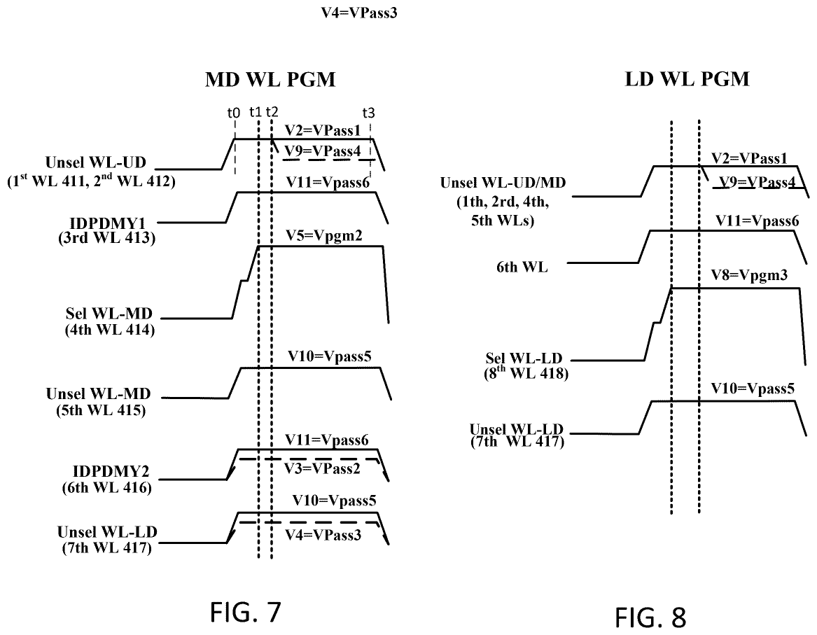

FIG. 7 is a schematic diagrams illustrating voltages applied to various word lines while programming the second deck 604b of a three-deck memory device 600. As noted above, in the present example of FIGS. 6-8, the memory device 600 is configured to program the first deck 604a, the second deck 604b and the third deck 604c sequentially. Therefore, without limiting to any particular theory, when programming a second memory cell 520-2 of the second deck 604b, the first deck 604a can be in a programmed state with a lower channel potential while the third deck 604c can be in an erased state with a higher channel potential. The deck in the programmed state can follow the two-step process to reduce the pass voltage as described above with reference to FIG. 5, while the deck in the erased state can take the soft-cut process as described above with reference to FIG. 4. The combination of the two-step process and the soft-cut process can further improve pass disturb without sacrificing boosting potential provided by a selected word line.

As illustrated in FIG. 7, for programming the second memory cell 520-2 in the plurality of memory cells of the second deck 604b, the peripheral circuit 130 is configured to (1) apply the second program voltage Vpgm2 to a selected word line (e.g., the fourth word line 414) of the second deck 604b, where the fourth word line 414 is coupled to the second memory cell 520-2 of the second deck 604b; (2) apply the first pass voltage Vpass1 to at least one unselected word line (e.g., the first word line 411, the second word line 412) of the first deck 604a, and after a predetermined time period, reduce the first pass voltage Vpass1 to the fourth pass voltage Vpass4; (3) apply the sixth pass voltage Vpass6 to at least one unselected word line (e.g., the third word line 413) between the first word line 411 of the first deck 604a and the fourth word line 414 of the second deck 604b; (4) apply the second pass voltage Vpass2 to an unselected word line (e.g., the sixth word line 416) that is between fourth word line 414 of the second deck 604b and the seventh word line 417 of the third deck 604c; and (5) apply the third pass voltage Vpass3 to an unselected word line (e.g., the seventh word line 417) of the third deck 604c.

In some implementations, the first pass voltage Vpass1 is greater than the third pass voltage Vpass3, and the third pass voltage Vpass3 is greater than the second pass voltage Vpass2. In some implementations, the second pass voltage Vpass2 is greater than or equal to 50% of the first pass voltage Vpass1. In some implementations, the third pass voltage Vpass3 is greater than or equal to 70% of the first pass voltage Vpass1.

In some implementations, the memory device 600 includes two or more dummy word lines near the interface between the second deck 604b and the third deck 604c, and the two or more dummy word lines includes the sixth word line 416. In some implementations, the two or more dummy word lines that are near the interface between the second deck 604b and the third deck 604c are all in the second deck 604b. In some implementations, the two or more dummy word lines that are near the interface between the second deck 604b and the third deck 604c are all in the third deck 604c. In some implementations, some dummy word lines are in the second deck 604b, and other dummy word lines are in the third deck 604c. In some implementations, the two or more dummy word lines are applied with the same voltages (e.g., Vpass2) when programming the second memory cell in the second deck 604b. In some implementations, the two or more dummy word lines are applied with different voltages when programming the second memory cell in the second deck 604b. For example, the dummy word lines that are closer to the fourth word line 414 of the second deck 604b are applied with Vpass2, but the dummy word lines that are closer to the seventh word line 417 of the third deck 604c are applied with a voltage with a value between Vpass2 and Vpass3. In some implementations, the voltages that are applied to the dummy word lines gradually increase as the dummy word lines move further from the fourth word line 414 and closer towards the seventh word line 417.

FIG. 8 is a schematic diagrams illustrating voltages applied to various word lines while programming the third deck 604c of a three-deck memory device 600. In some implementations, for programming a third memory cell 520-3 in the plurality of memory cells of the third deck 604c, the peripheral circuit 130 is configured to (1) apply a third program voltage Vpgm3 to an eighth word line 418 of the third deck 604c, where the eighth word line 418 is coupled to the third memory cell 520-3 of the third deck 604c; (2) apply the first pass voltage Vpass1 to the unselected word lines of the first deck 604a and the second deck 604b, and after the predetermined time period, reduce the first pass voltage Vpass1 to the fourth pass voltage Vpass4 on these word lines; (3) apply the sixth pass voltage Vpass6 to the sixth word line 416; and (4) and apply the fifth pass voltage Vpass5 to at least one unselected word line (e.g., the seventh word line 417) of the third deck 604c.

In some implementations, the third program voltage Vpgm3 is greater than the first pass voltage Vpass1. The third program voltage Vpgm3 can be identical to or different from the first program voltage Vpgm1 and/or the second program voltage Vpgm2. The third program voltage Vpgm3 can also be referred to as an eighth voltage V8 in the present disclosure.

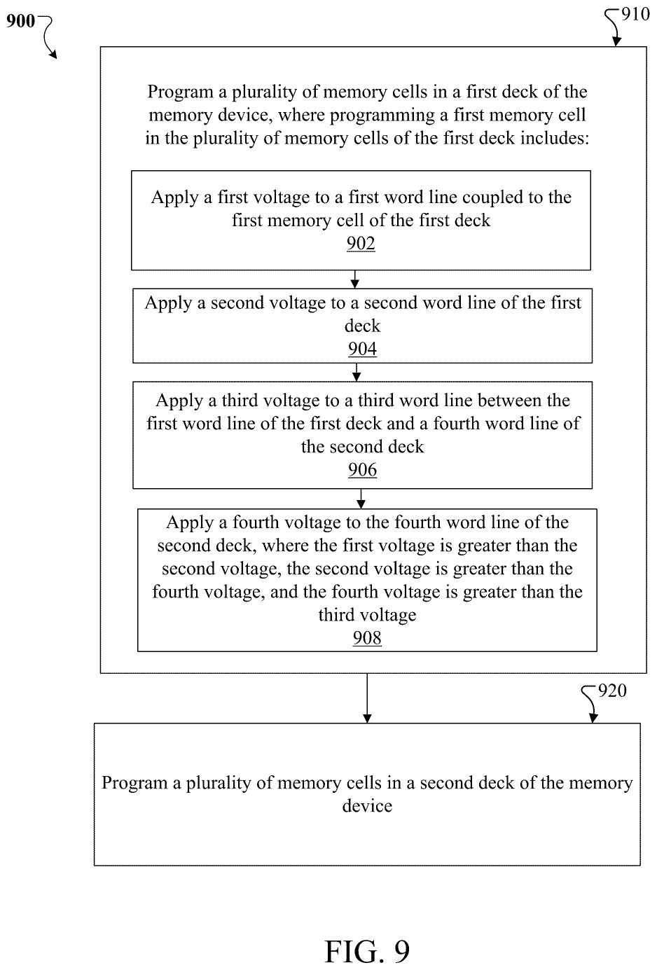

FIG. 9 illustrates a flow chart of an example process for programming a memory device. The memory device can be, e.g., the memory device 100 of FIGS. 1A, 1B and 2, the memory device 500 of FIG. 3A, the memory device 550 of FIG. 3B, the memory device 400 of FIGS. 4 and 5, or the memory device 600 of FIGS. 6-8.

At step 910, a plurality of memory cells in a first deck of the memory device is programmed. Programming the first memory cell in the plurality of memory cells of the first deck includes the following steps: (1) applying a first voltage to a first word line coupled to the first memory cell of the first deck (step 902); (2) applying a second voltage to a second word line of the first deck (step 904); (3) applying a third voltage to a third word line between the first word line of the first deck and a fourth word line of the second deck (step 906); and (4) applying a fourth voltage to the fourth word line of the second deck, where the first voltage is greater than the second voltage, the second voltage is greater than the fourth voltage, and the fourth voltage is greater than the third voltage (step 908). The first memory cell can be, e.g., the first memory cell 520-1 of FIGS. 4-8. The first deck can be, e.g., the first deck 504a of FIGS. 3A-3B, the first deck 404a of FIGS. 4-5, or the first deck 604a of FIGS. 6-8. The first word line can be, e.g., the first word line 411 of FIGS. 4-8. The second word line can be, e.g., the second word line 412 of FIGS. 4-8. The third word line can be, e.g., the third word line 413 of FIGS. 4-8. The fourth word line can be, e.g., the fourth word line 414 of FIGS. 4-8. The first voltage can be, e.g., the first program voltage Vpgm1. The second voltage can be, e.g., the first pass voltage Vpass1. The third voltage can be, e.g., the second pass voltage Vpass2. The fourth voltage can be, e.g., the third pass voltage Vpass3.

At step 920, a plurality of memory cells in a second deck of the memory device is programmed. The second deck can be, e.g., the second deck 504b of FIGS. 3A-3B, the second deck 404b of FIGS. 4-5, or the second deck 604b of FIGS. 6-8.

In some implementations, programming a second memory cell in the plurality of memory cells of the second deck includes: applying a fifth voltage to the fourth word line coupled to the second memory cell of the second deck, wherein the fifth voltage is greater than the second voltage; applying the second voltage to the first word line and the second word line, and after a predetermined time period, reducing the second voltage to the ninth voltage; applying an eleventh voltage to the third word line; and applying a tenth voltage to a fifth word line of the second deck. The first memory cell of the first deck is programmed before programming the second memory cell of the second deck. The fifth voltage can be, e.g., the second program Vpgm2. The second memory cell can be, e.g., the second memory cell 520-2 of FIGS. 4-8. The predetermined time period can be, e.g., the time period between t0 and t2 of FIGS. 5 and 7. The ninth voltage can be, e.g., the fourth pass voltage Vpass4. The tenth voltage can be, e.g., the fifth pass voltage Vpass5. The eleventh voltage can be, e.g., the sixth pass voltage Vpass6.

In some implementations, a plurality of memory cells in a third deck of the memory device is programmed, where the second deck is between the first deck and the third deck. The third deck can be, e.g., the third deck 604c of FIGS. 6-8.

In some implementations, programming the first memory cell in the plurality of memory cells of the first deck further includes applying the fourth voltage to a seventh word line of the third deck and a sixth word line between the fourth word line of the second deck and the seventh word line of the third deck. The sixth word line can be, e.g., the sixth word line 416 of FIGS. 6-8. The seventh word line can be, e.g., the seventh word line 417 of FIGS. 6-8.

In some implementations, programming the second memory cell in the plurality of memory cells of the second deck further includes: applying the third voltage to the sixth word line; and applying the fourth voltage to the seventh word line.

In some implementations, programming a third memory cell in the plurality of memory cells of the third deck includes: applying an eighth voltage to an eighth word line coupled to the third memory cell of the third deck, wherein the eighth voltage is greater than the second voltage; applying the second voltage to the first word line, the second word line, the fourth word line and the fifth word line, and after the predetermined time period, reducing the second voltage to the ninth voltage; apply the eleventh voltage to the sixth word line; and applying the tenth voltage to the seventh word line. The third memory cell of the third deck is programmed after programming the second memory cell of the second deck. The third memory cell can be, e.g., the third memory cell 520-3 of FIGS. 6-8. The eighth voltage can be, e.g., the third program voltage Vpgm3. The eighth word line can be, e.g., the eighth word line 418 of FIGS. 6-8.

In some implementations, the third voltage is greater than or equal to 50% of the second voltage. In some implementations, the third voltage is smaller than the eleventh voltage. In some implementations, the fourth voltage is smaller than the tenth voltage.

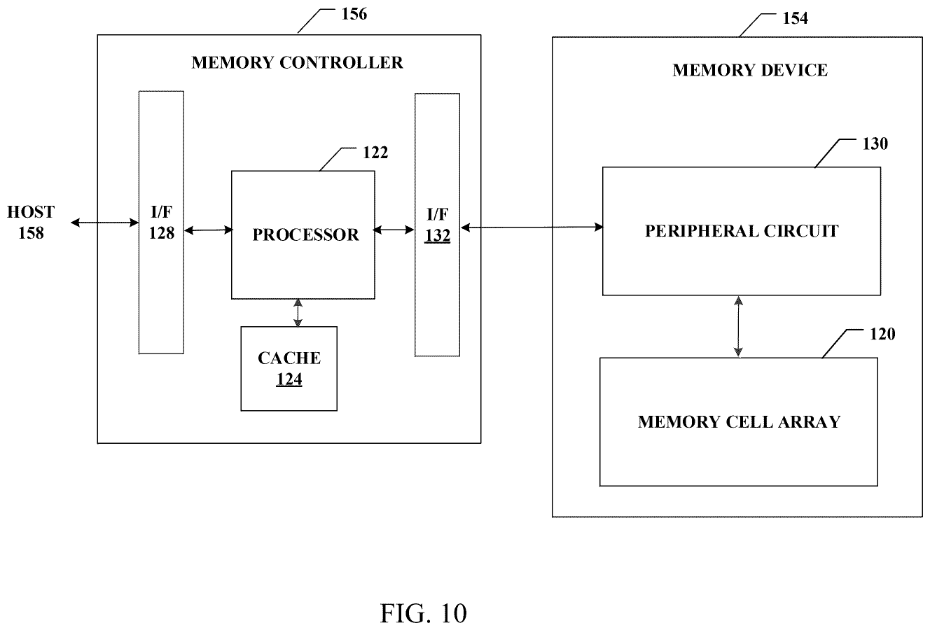

FIG. 10 illustrates a block diagram of an example memory controller 156 and an example memory device 154, in accordance with some aspects of the present disclosure. The memory controller 156 can include one or more processors 122, and one or more memories including one or more of a cache 124 and/or another type of data store. The memory controller 156 can also include an interface (I/F) 128 (also referred to as a “front-end interface”) to a host 158 and an interface (I/F) 132 (also referred to as a “back-end interface”) to a memory device 154. In some implementations, the interface 128 can receive instructions and data from the host 158 and forward the instructions and data to the processors 122, respectively. In some implementations, the interface 132 can transfer control signals and data from the processors 122 to the memory device 154.

In some implementations, the memory device includes a memory cell array (also called memory array structure) 120 and a peripheral circuit 130. The peripheral circuit 130 is coupled to the memory cell array 120 and configured to control the memory cell array 120. In some implementations, the peripheral circuit 130 is coupled to the memory controller 156 through the interface 132.

In some implementations, the memory device can be, e.g., the memory device 100 of FIGS. 1A, 1B and 2, the memory device 500 of FIG. 3A, the memory device 550 of FIG. 3B, the memory device 400 of FIGS. 4 and 5, or the memory device 600 of FIGS. 6-8.

In some implementations, the processors 122 can include an Arithmetic Logic Unit (ALU) configured to perform arithmetic and/or logical operations. The memory device 154, the one or more memories of the memory controller 156 such as the cache 124, or a combination of these can store programming instructions which, when loaded into the processors 122, can be executed by the processors 122 to perform various functions of the memory controller 156, such as the functions described in this disclosure. As an example, the memory controller 156 is configured to perform functions such as sending read commands, page transfer commands, and read-out commands, and performing soft decoding based on the read-out data.

In some implementations, the peripheral circuit 130 can include digital, analog, and/or mixed-signal circuits to support functions of the memory block, such as a page buffer.

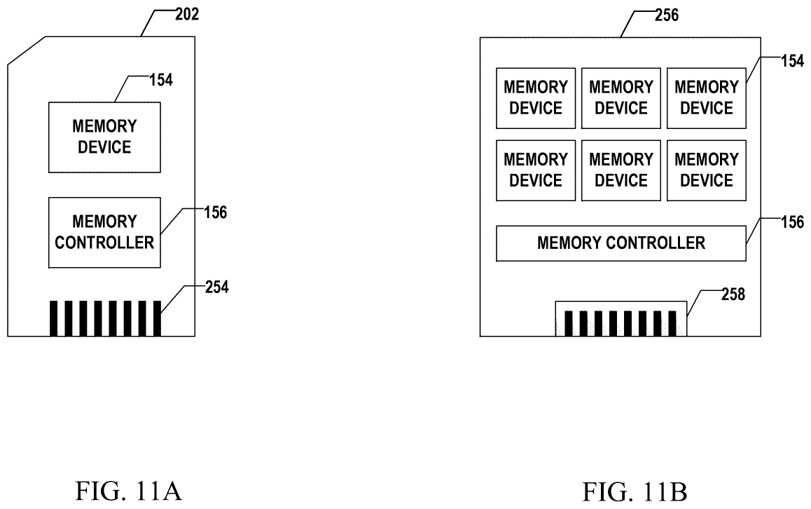

FIGS. 11A-11B illustrate example storage products, according to some implementations of the present disclosure. The memory controller 156 and the one or more memory devices 154 can be integrated into various types of storage devices. For example, the memory controller 156 and the one or more memory devices 154 can be packaged in a universal flash storage (UFS) package or an eMMC package. In one example as shown in FIG. 11A, the memory controller 156 and a single memory device 154 can be integrated into a memory card 202. The memory card 202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. The memory card 202 can further include a memory card connector 254 coupling the memory card 202 with a host (e.g., host 158 in FIG. 10). In another example as shown in FIG. 11B, the memory controller 156 and multiple memory devices 154 can be integrated into an SSD 256. The SSD 256 can further include an SSD connector 258 that couples the SSD 256 with a host (e.g., host 158 in FIG. 10). In some implementations, the storage capacity and/or the operation speed of the SSD 256 is greater than those of the memory card 202.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one implementation,” “an implementation,” “an example implementation,” “some implementations,” “some implementations,” “one implementation,” “an implementation,” “an example implementation,” etc., indicate that the implementation described can include a particular feature, structure, or characteristic, but every implementation can not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

As used in this disclosure, the term “substantially” or “substantial” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a memory array structure comprising a first deck and a second deck, each comprising a plurality of memory cells coupled to a corresponding plurality of word lines; and
a peripheral circuit coupled to the memory array structure,
wherein for programming a first memory cell in the plurality of memory cells of the first deck, the peripheral circuit is configured to:
apply a first voltage to a first word line coupled to the first memory cell of the first deck;
apply a second voltage to a second word line of the first deck;
apply a third voltage to a third word line between the first word line of the first deck and a fourth word line of the second deck; and
apply a fourth voltage to the fourth word line of the second deck,
wherein the first voltage is greater than the second voltage, the second voltage is greater than the fourth voltage, and the fourth voltage is greater than the third voltage.

2. The semiconductor device of claim 1, wherein the fourth word line is coupled to a second memory cell of the plurality of memory cells of the second deck, and the peripheral circuit is configured to program the first memory cell of the first deck before programming the second memory cell of the second deck.

3. The semiconductor device of claim 2, wherein for programming the second memory cell of the second deck, the peripheral circuit is configured to:
apply a fifth voltage to the fourth word line coupled to the second memory cell of the second deck, wherein the fifth voltage is greater than the second voltage;
apply the second voltage to the first word line and the second word line, and after a predetermined time period, reduce the second voltage to a ninth voltage;
apply an eleventh voltage to the third word line; and
apply a tenth voltage to a fifth word line of the second deck.

4. The semiconductor device of claim 3, wherein the third voltage is smaller than the eleventh voltage.

5. The semiconductor device of claim 3, wherein the fourth voltage is smaller than the tenth voltage.

6. The semiconductor device of claim 3, wherein the peripheral circuit is configured to reduce the second voltage to the ninth voltage that is applied to the first word line and the second word line after applying the fifth voltage to the fourth word line.

7. The semiconductor device of claim 3, wherein the tenth voltage is different from the second voltage.

8. The semiconductor device of claim 3,
wherein the memory array structure comprises a third deck including a plurality of memory cells, the second deck being between the first deck and the third deck, and
wherein for programming the first memory cell in the plurality of memory cells of the first deck, the peripheral circuit is further configured to apply the fourth voltage to a seventh word line of the third deck and to a sixth word line between the fourth word line of the second deck and the seventh word line of the third deck.

9. The semiconductor device of claim 8, wherein for programming the second memory cell in the plurality of memory cells of the second deck, the peripheral circuit is further configured to:
apply the third voltage to the sixth word line; and
apply the fourth voltage to the seventh word line.

10. The semiconductor device of claim 9, wherein the peripheral circuit is configured to program a third memory cell in the plurality of memory cells of the third deck after programming the second memory cell of the second deck, and for programming the third memory cell in the plurality of memory cells of the third deck, the peripheral circuit is configured to:
apply an eighth voltage to an eighth word line coupled to the third memory cell of the third deck, wherein the eighth voltage is greater than the second voltage;
apply the second voltage to the first word line, the second word line, the fourth word line, and the fifth word line, and after the predetermined time period, reduce the second voltage to the ninth voltage;
apply the eleventh voltage to the sixth word line; and
apply the tenth voltage to the seventh word line.

11. The semiconductor device of claim 1, wherein the third word line is a dummy word line.

12. The semiconductor device of claim 8, wherein the sixth word line is a dummy word line.

13. The semiconductor device of claim 1, wherein the first deck is coupled to a bit line, and the second deck is coupled to a source line.

14. A method for programming a memory device, comprising:
programming a plurality of memory cells in a first deck of the memory device; and
programming a plurality of memory cells in a second deck of the memory device,
wherein programming a first memory cell in the plurality of memory cells of the first deck comprises:
applying a first voltage to a first word line coupled to the first memory cell of the first deck;
applying a second voltage to a second word line of the first deck;
applying a third voltage to a third word line between the first word line of the first deck and a fourth word line of the second deck; and
applying a fourth voltage to the fourth word line of the second deck,
wherein the first voltage is greater than the second voltage, the second voltage is greater than the fourth voltage, and the fourth voltage is greater than the third voltage.

15. The method of claim 14, wherein programming a second memory cell in the plurality of memory cells of the second deck comprises:
applying a fifth voltage to the fourth word line coupled to the second memory cell of the second deck, wherein the fifth voltage is greater than the second voltage;
applying the second voltage to the first word line and the second word line, and after a predetermined time period, reducing the second voltage to a ninth voltage;
applying an eleventh voltage to the third word line; and
applying a tenth voltage to a fifth word line of the second deck,
wherein the first memory cell of the first deck is programmed before programming the second memory cell of the second deck.

16. The method of claim 15, comprising:
programming a plurality of memory cells in a third deck of the memory device, the second deck being between the first deck and the third deck,
wherein programming the first memory cell in the plurality of memory cells of the first deck further comprises applying the fourth voltage to a seventh word line of the third deck and to a sixth word line between the fourth word line of the second deck and the seventh word line of the third deck.

17. The method of claim 16, wherein programming the second memory cell in the plurality of memory cells of the second deck further comprises:
applying the third voltage to the sixth word line; and
applying the fourth voltage to the seventh word line.

18. The method of claim 17, wherein programming a third memory cell in the plurality of memory cells of the third deck comprises:
applying an eighth voltage to an eighth word line coupled to the third memory cell of the third deck, wherein the eighth voltage is greater than the second voltage;
applying the second voltage to the first word line, the second word line, the fourth word line, and the fifth word line, and after the predetermined time period, reducing the second voltage to the ninth voltage;
applying the eleventh voltage to the sixth word line; and
applying the tenth voltage to the seventh word line,
wherein the third memory cell of the third deck is programmed after programming the second memory cell of the second deck.

19. The method of claim 15, wherein the third voltage is smaller than the eleventh voltage.

20. A system, comprising:
a memory device, comprising:
a memory array structure comprising a first deck and a second deck, each comprising a plurality of memory cells coupled to a corresponding plurality of word lines; and
a peripheral circuit coupled to the memory array structure,
wherein for programming a first memory cell in the plurality of memory cells of the first deck, the peripheral circuit is configured to:
apply a first voltage to a first word line coupled to the first memory cell of the first deck;
apply a second voltage to a second word line of the first deck;
apply a third voltage to a third word line between the first word line of the first deck and a fourth word line of the second deck; and
apply a fourth voltage to the fourth word line coupled to a second memory cell in the plurality of memory cells of the second deck,
wherein the first voltage is greater than the second voltage, the second voltage is greater than the fourth voltage, and the fourth voltage is greater than the third voltage, and wherein the peripheral circuit is configured to program the first memory cell of the first deck before programming the second memory cell of the second deck; and
a memory controller coupled to the memory device and configured to operate the memory device.
